(19) United States
(12) Patent Application Publication
(10) Pub. No.: US 2012/0161766 A1
(43) Pub. Date: Jun. 28, 2012

(54) CONCURRENT OPTIMIZATION OF RF POWER AND RF FIELD UNIFORMITY IN MRI

(75) Inventors: Paul R. Harvey, Best (NL); Ronaldus F.J. Holthuizen, Eindhoven (NL); Willem M. Prins, Eindhoven (NL); Franciscus J.M. Benschop, 'S-Hertogenbosch (NL)

(73) Assignee: KONINKLIJKE PHILIPS ELECTRONICS N.V., EINDHOVEN (NL)

(21) Appl. No.: 13/393,234

(22) PCT Filed: Aug. 5, 2010
(86) PCT No.: PCT/IB2010/053558

§ 371 Date: Feb. 29, 2012

Related U.S. Application Data
(60) Provisional application No. 61/243,196, filed on Sep. 17, 2009.

(51) Int. Cl. G01R 33/48

(52) U.S. Cl. 324/309

(57) ABSTRACT

A magnetic resonance method comprising: loading a subject into a magnetic resonance scanner; with the subject loaded into the magnetic resonance scanner, acquiring B1 maps (72) for a plurality of radio frequency transmit channels of the magnetic resonance scanner; shimming the plurality of radio frequency transmit channels and setting a radio frequency transmit power for the shimmed plurality of radio frequency transmit channels using the acquired B 1 maps to generate optimized amplitude and phase parameters (98) for the plurality of radio frequency transmit channels; acquiring magnetic resonance imaging data of the subject loaded into the magnetic resonance scanner including exciting magnetic resonance by operating the plurality of radio frequency transmit channels using the optimized amplitude and phase parameters; generating a reconstructed image from the acquired magnetic resonance imaging data; and displaying the reconstructed image.

The following relates to the magnetic resonance arts, medical imaging arts, and related arts.

Magnetic resonance (MR) imaging can be performed using sensitivity encoding (SENSE) or other parallel imaging techniques. In some parallel imaging techniques, multiple radio frequency (RF) transmit coils are used, or a single RF transmit coil may be driven using independent drive channels. As an example of the latter arrangement, a birdcage coil having “I” and “Q” drive ports may be driven using independent radio frequency power inputs to the I and Q channels. In such multiple RF transmit channel configurations, each transmit channel generally has an independent drive amplitude and phase, so that for N RF transmit channels there are 2N drive parameters.

To calibrate the RF transmit power, one or more power optimization acquisitions are performed using a multi-channel transmit configuration. The power optimization acquisitions are used to scale the RF transmit power to a desired level. A power optimization acquisition typically employs a 1D projection, which can be acquired relatively quickly and provides an average RF transmit field power level measure for use in the RF transmit power optimization.

In some cases, the RF transmit channels of a multi-channel transmit configuration are trimmed to provide a more uniform RF transmit field. In a usual approach, a B₁ map is acquired and optimized respective to the B₁ transmit field uniformity. This process is known as RF transmit field shimming.

Existing multi-channel RF transmit preparation techniques provide limited accuracy respective to RF transmit power. Because the 1D projection provides an average RF transmit power measure, it may fail to accurately measure the RF transmit power at a location of interest, such as over the volume of a heart, brain, or other organ that is the imaging target. This problem is enhanced at high magnetic fields due to shorter RF wavelength and enhanced spatial non-uniformity. Patient loading effects are also larger at high magnetic field due to more pronounced electrical properties of biological tissue.

The following provides new and improved apparatuses and methods which overcome the above-referenced problems and others.

In accordance with one disclosed aspect, a magnetic resonance method comprises: acquiring B1 maps for a plurality of radio frequency transmit channels of a magnetic resonance scanner; and computing optimized amplitude and phase parameters for the plurality of radio frequency transmit channels using the acquired B1 maps such that operating the plurality of radio frequency transmit channels together in a multi-channel transmit mode using the optimized amplitude and phase parameters generates a radio frequency transmit field that is both (i) shimmed respective to radio frequency transmit field uniformity and (ii) optimized respective to a radio frequency transmit power metric; wherein the computing is performed by a digital processor.

In accordance with another disclosed aspect, a magnetic resonance system is disclosed, comprising: a magnetic resonance scanner including a plurality of radio frequency transmit channels; and a processor configured to perform a method as set forth in the immediately preceding paragraph in cooperation with the magnetic resonance scanner.

In accordance with another disclosed aspect, a storage medium stores instructions executable by a digital processor to perform a method comprising: optimizing relative amplitude parameters and phase parameters for a plurality of radio frequency transmit channels using B1 maps corresponding to the plurality of radio frequency transmit channels such that operating the plurality of radio frequency transmit channels together in a multi-channel transmit mode using the optimized relative amplitude parameters and optimized phase parameters generates a radio frequency transmit field that is shimmed respective to radio frequency transmit field uniformity; and scaling the relative amplitude parameters using the B1 maps to generate optimized amplitude parameters such that operating the plurality of radio frequency transmit channels together in a multi-channel transmit mode using the optimized amplitude parameters and optimized phase parameters generates a radio frequency transmit field that is optimized respective to a radio frequency transmit power metric.

In accordance with another disclosed aspect, a magnetic resonance method comprises: loading a subject into a magnetic resonance scanner; with the subject loaded into the magnetic resonance scanner, acquiring B1 maps for a plurality of radio frequency transmit channels of the magnetic resonance scanner; shimming the plurality of radio frequency transmit channels and setting a radio frequency transmit power for the shimmed plurality of radio frequency transmit channels using the acquired B1 maps to generate optimized amplitude and phase parameters for the plurality of radio frequency transmit channels; acquiring magnetic resonance imaging data of the subject loaded into the magnetic resonance scanner including exciting magnetic resonance by operating the plurality of radio frequency transmit channels using the optimized amplitude and phase parameters; generating a reconstructed image from the acquired magnetic resonance imaging data; and displaying the reconstructed image.

One advantage resides in providing more accurate radio frequency transmit power optimization.

Another advantage resides in reduction in MR acquisition time.

Further advantages will be apparent to those of ordinary skill in the art upon reading and understanding the following detailed description.

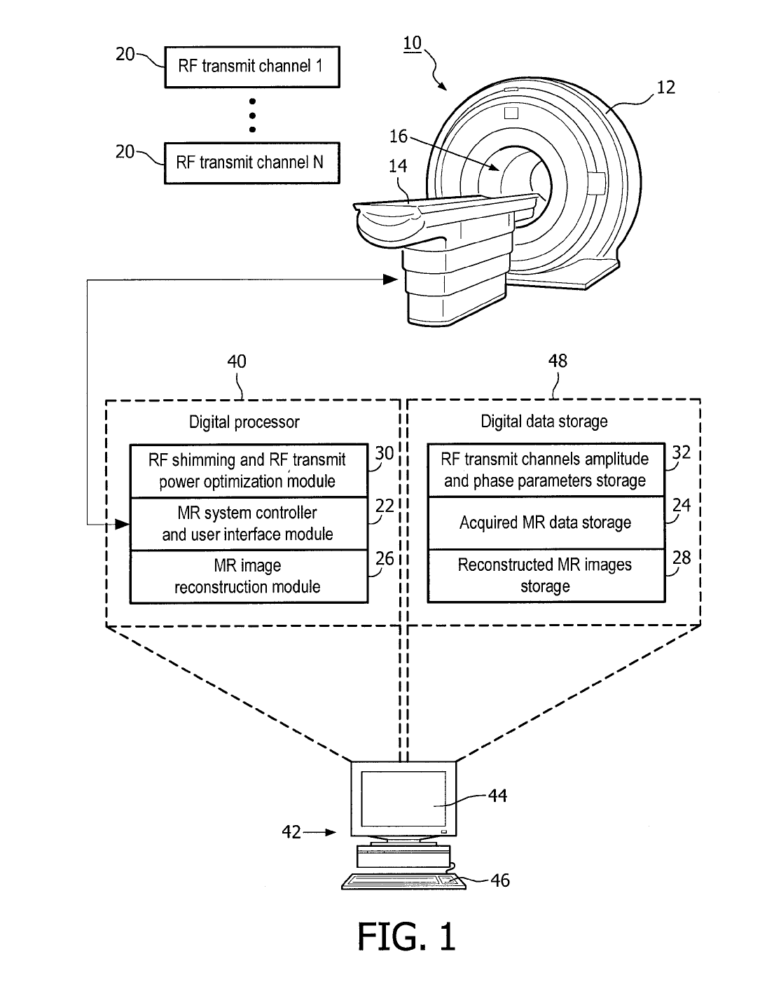

FIG. 1 diagrammatically illustrates a magnetic resonance system.

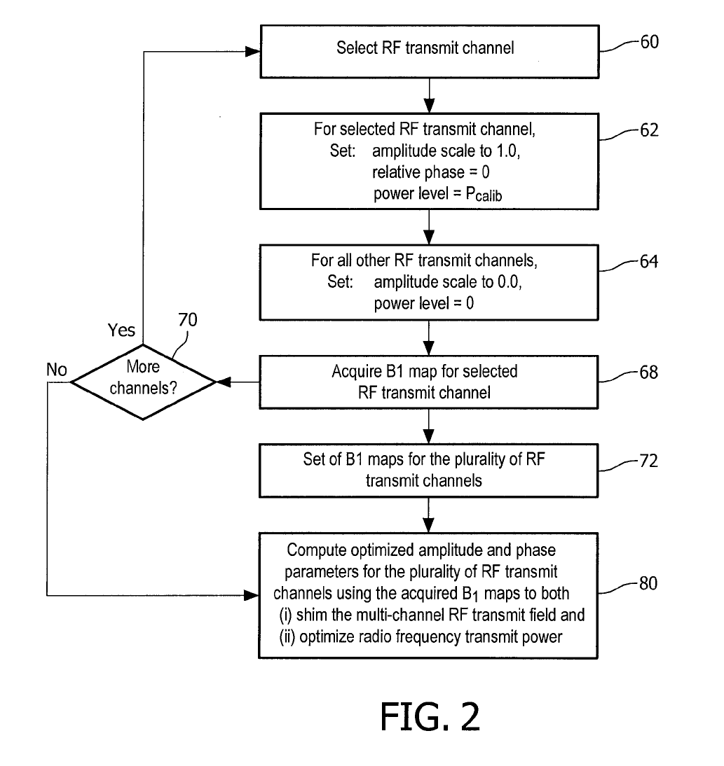

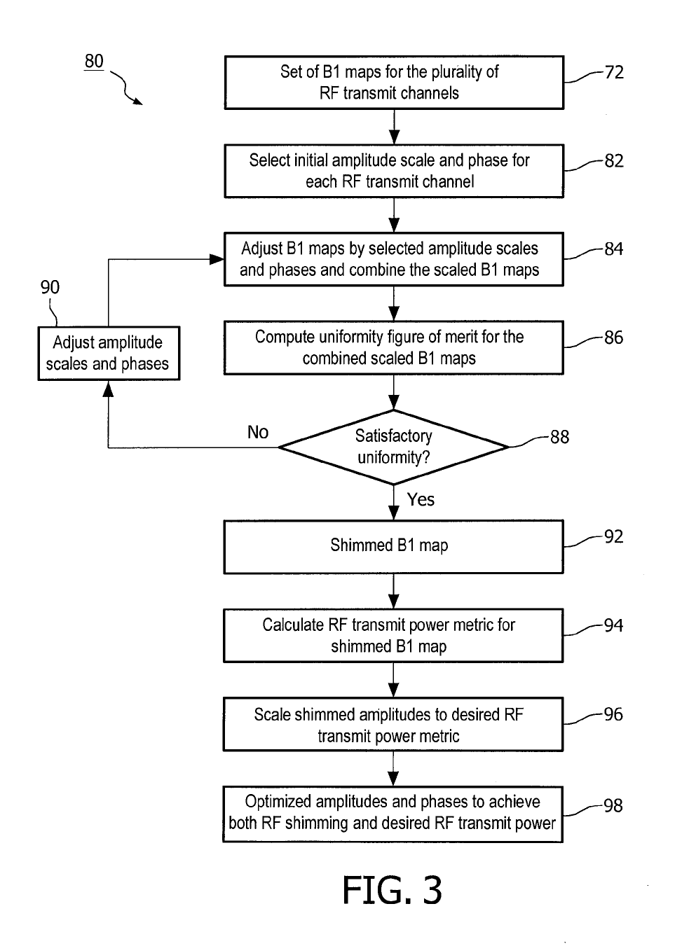

FIGS. 2 and 3 diagrammatically illustrate a combined radio frequency (RF) shimming and RF transmit power adjustment performed by the RF shimming and RF transmit power optimization module of the system of FIG. 1.

With reference to FIG. 1, a magnetic resonance (MR) scanner 10 includes a housing 12 that houses or supports components (not illustrated) such as a main magnet generating a static (B0) magnetic field and a set of magnetic field gradient coils, and an MR subject loading system 14 such as a subject couch that can be translated into and out of an imaging region which in the case of the illustrated MR scanner 10 lies within a bore 16 of the MR scanner 10. The illustrated magnetic resonance scanner 10 is an Achieva™ MR scanner available from Koninklijke Philips Electronics N.V. (Eindhoven, the Netherlands); however, substantially any MR scanner can be employed.

A plurality of radio frequency (RF) transmit channels 20 are provided, as shown in FIG. 1 where N radio frequency transmit channels 20 are diagrammatically indicated, with N being an integer greater than or equal to two. The plurality of radio frequency transmit channels 20 are operable in a multi-channel transmit mode to generate a radio frequency transmit field, sometimes denoted as a B1 transmit field. The RF frequency of the B1 transmit field is preferably at or near a magnetic resonance frequency. For a given static (B0) magnetic field, the magnetic resonance frequency is given by the product of the static magnetic field strength (|B0|) and a gyrometric constant (γ) which is a property of the nuclei intended to undergo nuclear magnetic resonance.

The plurality of radio frequency transmit channels 20 can be variously embodied. For example, in some embodiments the plurality of radio frequency transmit channels 20 is embodied as a single birdcage-type volumetric radio frequency coil having I and Q ports that are independently driven, such that the number of RF transmit channels N=2 for such embodiments. In other embodiments, the plurality of radio frequency transmit channels 20 is embodied as a set of N independent coil elements, such as N independent surface coils, or N decoupled rods or rungs of a degenerate whole-body RF coil, or so forth. In these embodiments, the N independent coil elements may be variously configured, for example as separately housed coil elements, or coil elements that are electrically isolated but physically housed in a common housing (for example, a dedicated N-element coil array assembly), or so forth.

Additionally, one or more magnetic resonance receive coils are provided. In some embodiments one, some, or all of the RF transmit channels of the plurality of RF transmit channels 20 are configured as transmit/receive coils that are suitably switched to a receive mode to receive the magnetic resonance. In other embodiments, one or more magnetic resonance receive coils (not illustrated) that are separate from the plurality of RF transmit channels 20 are provided to perform the magnetic resonance receive operation.

With continuing reference to FIG. 1, the MR system further includes an MR system controller and user interface module 22 by which a radiologist or other user can interface with the MR scanner 10 to cause the MR scanner 10 to acquire MR imaging data and to perform other functions such as automated loading and unloading of an imaging subject via the MR subject loading system 14.

In a typical imaging sequence the subject to be imaged is loaded into the imaging region of the bore 16 using the loading system 14, the RF transmit channels of the plurality of RF transmit channels 20 are energized in a multi-channel transmit mode to excite magnetic resonance in the subject, the magnetic field gradient coils are operated before, during, and/or after the magnetic resonance excitation in order to spatially limit and/or spatially encode or otherwise manipulate the magnetic resonance, and the magnetic resonance is received via the MR receive coils and stored in an acquired MR data storage 24. The acquired MR data are suitably reconstructed by an MR image reconstruction module 26 to generate one or more reconstructed MR images that are stored in a reconstructed MR images storage 28. The reconstruction module 26 employs a reconstruction algorithm that is operative with the spatial encoding employed during acquisition of the MR imaging data. For example, if the MR imaging data are acquired as k-space samples using Cartesian encoding, then a Fourier transform-based reconstruction algorithm may be suitably employed by the reconstruction module 26.

In this illustrative imaging sequence, the RF transmit channels of the plurality of RF transmit channels 20 are energized in a multi-channel transmit mode to excite magnetic resonance in the subject. In the multi-channel transmit mode each RF transmit channel is independently controlled in terms of RF excitation amplitude and phase. Thus, for N RF channels there are 2N independently adjustable parameters. It is desired to adjust these 2N parameters to provide a substantially (spatially) uniform B1 transmit field and to provide a B1 transmit field of a desired radio frequency transmit power. Adjusting the RF channels to provide a substantially uniform B1 transmit field is known as RF shimming. The adjustment of the RF channels to provide a desired radio frequency transmit power is typically done to provide a desired flip angle in the subject, such as a target 90° flip angle, or to limit the specific absorption rate (SAR) or another subject safety measure, or so forth. The uniformity of the B1 transmit field for a given set of 2N multi-channel transmit parameters can be substantially influenced by electrical and/or magnetic susceptibility properties of the subject undergoing imaging, so that the “optimal” transmit parameters are in general subject-specific. The influence of the subject on the B1 transmit field tends to increase as the static (B0) magnetic field increases.

With continuing reference to FIG. 1, the MR system further includes an RF shimming and RF transmit power optimization module 30 that optimizes the RF amplitudes and phases of the RF transmit channels of the plurality of RF transmit channels 20 based on acquired B1 maps for the individual RF transmit channels. The utilized B1 maps are preferably although not necessarily acquired with the subject loaded in order to account for the aforementioned subject loading effects on the B1 transmit field. The optimized amplitudes and phases are stored in an RF transmit channels amplitude and phase parameters storage 32 for recall and use by the MR system controller and user interface module 22 during subject imaging.

The processing modules 22, 26, 30 are suitably embodied by a digital processor 40, which in the illustrative embodiment of FIG. 1 is the processor of a computer 42. It is to be understood that the digital processor 40 may be a plurality of processors, such as in the case of a multi-core microprocessor, a microprocessor and cooperating graphical processing unit (GPU) or math co-processor, or so forth. Moreover, the digital processor 40 may be otherwise configured, such as a dedicated processor that is not part of a computer. Still further, the various processing modules 22, 26, 30 may be embodied by different processors and/or to include non-digital processor components—for example, the reconstruction module 26 may include an analog pipeline component. The user interfacing component of the MR system controller and user interface module 22 accesses suitable user interfacing hardware, such as an illustrated display 44 of the computer 42 for displaying MR scanner configuration, reconstructed images, or providing other user-perceptible output, and an illustrated keyboard 46 of the computer 42 for user input, or other user input device such as a mouse, trackball, touch-sensitive screen, or so forth for receiving user input. The various data storage components 24, 28, 32 are suitably embodied as one or more storage media of the computer 42, such as a hard disk drive, random access memory (RAM), or so forth. The data storage components 24, 28, 32 may also be embodied by other storage media such as a network-accessible picture archiving and communications system (PACS), an external hard drive, an optical disk, or so forth.

It is also to be understood that the various processing modules 22, 26, 30 can be embodied by a storage medium storing instructions that are executable by the illustrated processor 40 of the computer 42 or by another processor in order to perform the operations disclosed herein, including the operations performed by the module 30 including the computing of optimized amplitude and phase parameters for the plurality of radio frequency transmit channels 20 using acquired B1 maps to both (i) shim the multi-channel RF transmit field and (ii) optimize radio frequency transmit power. The storage medium storing such instructions may, for example, be a hard disk drive or other magnetic storage medium, or an optical disk or other optical storage medium, or a random access memory (RAM), read-only memory (ROM), flash memory or other electronic storage medium, or so forth.

With reference to FIGS. 2 and 3, an illustrative example of the optimized amplitude and phase parameters computation suitably performed by the RF shimming and RF transmit power optimization module 30 is described. The approaches disclosed herein perform both shimming and RF transmit power optimization using acquired B1 maps for the RF transmit channels. This avoids executing additional MR data acquisition to measure and adjust RF transmit power, and provides flexibility as to the choice of the radio frequency transmit power metric used in the power optimization. For example, the radio frequency transmit power metric can be the average RF transmit power over a region of interest (for example, encompassing the heart in the case of cardiac imaging), or can be the average RF transmit power in a slice of interest, or can be the RF transmit power at a point in space of interest.

The illustrative example of FIGS. 2 and 3 begins by acquiring a (complex) B1 map for each RF transmit channel. Toward this end, an RF transmit channel to be mapped is selected in an operation 60. In an operation 62, for the selected RF transmit channel the amplitude scale is set to 1.0, the relative phase is set to 0°, and the power level is set to a calibration power level denoted herein as P_{calib}. More generally, these parameters are set to chosen calibration or reference levels in operation 62—for example, it is contemplated to employ a reference relative phase of other than 0°. In an operation 64, for all RF transmit channels other than the selected RF transmit channel the amplitude scale is set to 0.0 and the power level is set to zero. In an operation 68, the B1 map is acquired for the selected RF transmit channel. In other words, in the operation 68 a B1 map is acquired using transmission from only the selected channel whose parameters are: amplitude scale=1.0; relative phase=0°; power level=P_{calib}. A looping or iteration operation 70 causes the operations 60, 62, 64, 68 to be repeated to select and map each RF transmit channel of the plurality of RF transmit channels 20, so as to generate a set of (complex) B1 maps 72 for the plurality of RF transmit channels 20.

In a suitable approach for the B1 mapping operation 68, a two- or three-dimensional B1 map of a slice or volume of interest (preferably inside or coincident with the loaded imaging subject) is acquired. The B1 mapping may suitably employ RF pulses of a pre-determined target B1 amplitude (e.g., amplitude scale 1.0) and the RF power (e.g., power P_{calib}). The power level P_{calib} can be a fixed and typically low power level, and is optionally derived from a traditional RF drive scale determination. The B1 map should map the complex B1 values (that is, the B1 values including phase information) and represent the actual B1 values or relative B1 values that are relative to a target or nominal B1 value. The B1 map for a given RF transmit channel represents the actual transmit sensitivity of that RF transmit channel.

With continuing reference to FIG. 2, once the set of B1 maps 72 for the plurality of RF transmit channels 20 is acquired, in a computation operation 80 the optimized amplitude and phase parameters are computed for the plurality of RF transmit channels 20 using the acquired B1 maps 72 to both: (i) shim the multi-channel RF transmit field; and (ii) optimize radio frequency transmit power.

With reference to FIG. 3, illustrative suitable processing implementing the computation operation 80 is described. The illustrative approach first computes the shimming to optimize spatial uniformity of the multi-channel RF transmit field, and then adjusts the amplitudes of the shimmed RF transmit channels to achieve a desired RF transmit power metric. The shimming implemented in FIG. 3 is iterative, and starts with an operation 82 in which an initial amplitude (or amplitude scale) and relative phase is selected for each RF transmit channel of the plurality of RF transmit channels 20. The initial amplitudes and phases are to be iteratively adjusted to iteratively improve the B1 transmit field uniformity—accordingly, the initial values are generally not critical, although having the initial values close to the final optimized values reduces the iterative computation time. In some embodiments, amplitude scale=1.0 and relative phase=0° is used as initial values for all RF transmit channels. Alternatively, if a priori information is available it can be used to set the initial values in the operation 82. For example, optimized amplitudes and phases determined for a previous similar subject (e.g., similar in weight, similar in body dimensions, or so forth) may be used as initial values. In an operation 84, the B1 maps 72 are adjusted based on these initial amplitude and phase values. This can be done on a pixel-by-pixel basis by multiplying the complex B1 value by the initial amplitude scale value and shifting the B1 phase by the initial relative phase value. The thusly adjusted B1 maps are then combined in the operation 84 to generate a B1 map that would be obtained in multi-channel transmit mode using the plurality of RF transmit channels 20 operated with the initial parameters selected in the operation 82.

In an operation 88, this B1 map that would be obtained in multi-channel transmit mode using the plurality of RF transmit channels 20 operated with the initial parameters selected in the operation 82 is analyzed respective to spatial uniformity. The operation 88 suitably employs a figure of merit comprising a measure of RF transmit field uniformity. In some embodiments, the coefficient of variance is used as the figure of merit measuring RF transmit field uniformity; however, other uniformity figures of merit can be employed. If the operation 88 finds that the uniformity is unsatisfactory (for example, the computed variance figure of merit is larger than an acceptable maximum variance threshold) then in an operation 90 the amplitudes (or amplitude scales) and phases are adjusted in an attempt to improve the figure of merit. The operation 90 can employ any suitable iterative adjustment algorithm, such computing the partial derivatives of the variance respective to the various amplitude and phase parameters and employing a gradient-descent improvement step. Processing then flows back to operation 84 to generate an adjusted B1 map that would be obtained in multi-channel transmit mode using the plurality of RF transmit channels 20 operated with the amplitude and phase parameters as adjusted by the adjustment operation 90, and a new figure of merit is computed in the operation 86 which is compared with the maximum variance threshold or other satisfactory uniformity criterion in the operation 88, and so forth iteratively until at the operation 88 it is determined that the iteratively adjusted parameters are now yielding a multi-channel transmit mode B1 map of satisfactory spatial uniformity. This final map is suitably considered as a shimmed B1 map 92.

The iterative shimming process implemented by the operations 82, 84, 86, 88, 90 is an illustrative example, and other shimming processes may be employed. In general, any fitting method may be used which determines the optimum relative amplitude and phase parameters by which to combine the individual B1 maps 72 for minimum coefficient of variance (or as measured by another uniformity optimization criterion). A brute force approach is also contemplated, which involves sequentially iterating phase and amplitude coefficients while testing the uniformity of the combined B1 map.

The shimmed B1 map 92 is representative of the shimmed B1 field that would exist inside the imaging subject upon application by the plurality of RF transmit channels 20 of the shimmed multi-channel RF excitation. The amplitudes optimized by the shimming operations 82, 84, 86, 88, 90 are optimized relative amplitudes, because it is the values of the optimized amplitudes relative to one another that determines the B1 transmit field uniformity in multi-channel transmit mode. Accordingly, the optimized relative amplitudes output by the shimming operations 82, 84, 86, 88, 90 do not (in general) provide any particular RF transmit power level. However, an advantageous property of the shimmed B1 map 92 is that the values can be directly related to the individual channel powers and phases for achieving a desired B1 amplitude (or, equivalently, for achieving a desired RF transmit power level).

Accordingly, the shimmed B1 map 92 is used to derive the RF power levels (that is, drive scales) by relating the known power levels used to acquire the individual channel B1 maps to the B1 field distribution and amplitude obtained following correction using the shim coefficients derived from the shimming analysis (operations 82, 84, 86, 88, 90). This ensures that the target B1 field is obtained accurately when driving the individual RF channels with the phase and amplitude coefficients determined to provide the most uniform excitation. Toward this end, an RF transmit power metric is computed for the shimmed B1 map 92 in an operation 94. The RF transmit power metric can be, for example: (i) average RF transmit power in a region of interest; (ii) average RF transmit power in a slice of interest; (iii) RF transmit power at a point in space of interest; or so forth. Because the complete shimmed B1 map 92 is available for processing by the operation 94, there is substantial flexibility in choosing an RF transmit power metric that is appropriate for the imaging task of interest. For example, if it is important to have a 90° flip angle at the center of the image, then the RF transmit power metric can be the RF transmit power at the center of the imaging volume. For imaging a slice, the choice of RF transmit power metric may be average RF transmit power over the slice.

The RF transmit power metric determined by the operation 94 is compared with a desired value for the RF transmit power metric to determine a power scaling factor in an operation 96, and the shimmed amplitudes for the RF transmit channels are scaled by the power scaling factor to arrive at the optimized amplitudes and phases 98 for achieving both RF shimming and desired RF transmit power. For example, if the RF transmit power metric determined by the operation 94 is denoted (in amplitude units) as B1ₘₑₐₛ and the desired value for the RF transmit power metric is denoted (again in amplitude units) as B1_{target}, then the scaling factor is B1_{target}/B1ₘₑₐₛ. The amplitudes are then suitably scaled by this scaling factor. In performing this adjustment, it should be noted that the choice of RF transmit power metric here is in amplitude units, and so the amplitudes being scaled by the scaling factor (B1_{target}/B1ₘₑₐₛ) results in the corresponding RF transmit power being scaled by the factor (B1_{target}/B1ₘₑₐₛ)². The choice of RF transmit power metric can be either in amplitude units or in power units. Using a power units example, if the RF transmit power metric determined by the operation 94 is denoted (in power units) as P1ₘₑₐₛ and the desired value for the RF transmit power metric is denoted (in power units) as P1_{target}, then the scaling factor for the amplitudes is (P1_{target}/P1ₘₑₐₛ)^{1/2}, and the corresponding RF transmit power is scaled by (P1_{target}/P1ₘₑₐₛ).

In the embodiment of FIG. 3, the shimming is performed first by illustrative operations 82, 84, 86, 88, 90, followed by RF transmit power optimization performed by operations 94, 96, 98, with both the shimming and the RF transmit power optimization using the acquired B₁ maps 72.

In other embodiments, the shimming and the RF transmit power optimization can be performed concurrently, in a single process, again using the acquired B₁ maps. For example, in one such embodiment the figure of merit employed in the decision block 88 is modified to be a figure of merit that combines (i) a measure of RF transmit field uniformity (such as the coefficient of variance) and (ii) a measure of RF transmit field power (such as the average B1 field over a slice or region of interest). In such an embodiment, for example, the figure of merit may be a weighted sum of (i) the coefficient of variance and (ii) a term (B1_{target}-B1ₘₑₐₛ)² which compares the measure of RF transmit field power (B1ₘₑₐₛ) with a target RF transmit field power (B1_{target}). With this modified figure of merit, the iterative operations 82, 84, 86, 88, 90 can concurrently perform the shimming (by optimizing the coefficient of variance term) and the RF transmit power (by optimizing the term term (B1_{target}-B1ₘₑₐₛ)²), with the weighting between the two terms selecting which aspect (field uniformity or RF transmit power optimization) dominates the optimization. In this embodiment, the operations 94, 96, 98 are suitably omitted since the modified figure of merit ensures that the optimization operations 82, 84, 86, 88, 90 optimize the RF transmit power metric.

In the B1 mapping approach of FIG. 2, the B1 map for each RF transmit channel is acquired by operating that channel alone in a B1 mapping sequence. However, other B1 mapping approaches can be used to generate the set of B1 maps 72. For example, an all-but-one mapping approach can be used, in which (for example) in each B1 mapping acquisition all channels are energized except one, and the B1 mapping acquisition is repeated multiple times (equal to the number N of RF transmit channels 20) and a different channel is not energized each time. In an all-but-one approach, the relative phases of each channel may be initially fixed as for quadrature excitation and subsequent B1 map acquisitions set the amplitude of a different channel to zero. Variations on this approach are also suitable, in which different groups of RF transmit channels are energized using a fixed relationship and the relationship is permuted each time a B1 map is acquired until as many B1 maps have been acquired as there are independent RF transmit channels. To convert the B1 mapping data into the set of B1 maps 72 for the N channels, the physical channels are mapped on to virtual channels (constructed from combinations of elements). Such all-but-one or other combinative mapping procedures can enhance robustness of the B1 mapping process, and can expedite the fitting procedure.

This application has described one or more preferred embodiments. Modifications and alterations may occur to others upon reading and understanding the preceding detailed description. It is intended that the application be construed as including all such modifications and alterations insofar as they come within the scope of the appended claims or the equivalents thereof.

1. A magnetic resonance method comprising:
acquiring B₁ maps for a plurality of radio frequency transmit channels of a magnetic resonance scanner; and
computing optimized amplitude and phase parameters for the plurality of radio frequency transmit channels using the acquired B₁ maps such that operating the plurality of radio frequency transmit channels together in a multi-channel transmit mode using the optimized amplitude and phase parameters generates a radio frequency transmit field that is both (i) shimmed respective to radio frequency transmit field uniformity and (ii) optimized respective to a radio frequency transmit power metric;
wherein the computing is performed by a digital processor.

2. The magnetic resonance method as set forth in claim 1, further comprising:
prior to acquiring the B₁ maps, loading a subject into the magnetic resonance scanner such that the B₁ maps are acquired with the subject loaded into the magnetic resonance scanner.

3. The magnetic resonance method as set forth in claim 2, further comprising:
acquiring magnetic resonance imaging data of the subject loaded into the magnetic resonance scanner using magnetic resonance excitation performed by operating the plurality of radio frequency transmit channels together in a multi-channel transmit mode using the optimized amplitude and phase parameters.

4. The magnetic resonance method as set forth in claim 3, further comprising:
reconstructing the acquired magnetic resonance imaging data to generate a reconstructed image of the subject; and
displaying the reconstructed image on a display.

5. The magnetic resonance method as set forth in claim 1, wherein acquiring the B₁ maps comprises:
(a) acquiring a B₁ map for a selected radio frequency transmit channel of the plurality of radio frequency transmit channels with only the selected radio frequency transmit channel operating; and
(b) repeating the acquiring operation (a) for different selections from the plurality of radio frequency transmit channels selected until a B₁ map is acquired for every radio frequency transmit channel of the plurality of radio frequency transmit channels.

6. The magnetic resonance method as set forth in claim 1, wherein acquiring the B₁ maps employs an all-but-one mapping procedure.

7. The magnetic resonance method as set forth in claim 1, wherein the computing comprises:
optimizing the phase parameters and relative amplitude parameters using the acquired B₁ maps such that operating the plurality of radio frequency transmit channels together in a multi-channel transmit mode using the optimized phase parameters and optimized relative amplitude parameters generates a radio frequency transmit field that is shimmed respective to radio frequency transmit field uniformity; and
scaling the optimized relative amplitude parameters to generate optimized amplitude parameters using the acquired B₁ maps such that operating the plurality of radio frequency transmit channels together in a multi-channel transmit mode using the optimized amplitude and phase parameters generates a radio frequency transmit field that is optimized respective to a radio frequency transmit power metric.

8. The magnetic resonance method as set forth in claim 1, wherein the radio frequency transmit power metric is selected from a group consisting of (i) average radio frequency transmit power in a region of interest, (ii) average radio frequency transmit power in a slice of interest, and (iii) radio frequency transmit power at a point in space of interest.

9. A magnetic resonance system comprising:
a magnetic resonance scanner including a plurality of radio frequency transmit channels; and
a processor configured to perform a method as set forth in claim 1 in cooperation with the magnetic resonance scanner.

10. A storage medium storing instructions executable by a digital processor to perform a method comprising:
optimizing relative amplitude parameters and phase parameters for a plurality of radio frequency transmit channels using B₁ maps corresponding to the plurality of radio frequency transmit channels such that operating the plurality of radio frequency transmit channels together in a multi-channel transmit mode using the optimized relative amplitude parameters and optimized phase parameters generates a radio frequency transmit field that is shimmed respective to radio frequency transmit field uniformity; and
scaling the relative amplitude parameters using the B₁ maps to generate optimized amplitude parameters such that operating the plurality of radio frequency transmit channels together in a multi-channel transmit mode using the optimized amplitude parameters and optimized phase parameters generates a radio frequency transmit field that is optimized respective to a radio frequency transmit power metric.

11. The storage medium as set forth in claim 10, wherein the optimizing and scaling are performed as separate operations with the scaling performed after the optimizing.

12. The storage medium as set forth in claim 10, wherein the optimizing and scaling are performed together as an iterative optimization respective to a figure of merit that combines a radio frequency transmit field uniformity measure and the radio frequency transmit power metric.

13. The storage medium as set forth in claim 10, wherein the stored instructions are further executable by a digital processor to perform a method comprising:
causing a magnetic resonance scanner to acquire the B₁ maps using the plurality of radio frequency transmit channels.

14. The storage medium as set forth in claim 13, wherein the stored instructions are further executable by a digital processor to perform a method comprising:
causing the magnetic resonance scanner to acquire magnetic resonance imaging data including operating the plurality of radio frequency transmit channels together in a multi-channel transmit mode using the optimized amplitude parameters and optimized phase parameters.

15. The storage medium as set forth in claim 14, wherein the stored instructions are further executable by a digital processor to perform a method comprising:
reconstructing the acquired magnetic resonance imaging data to generate a magnetic resonance image.

16. A magnetic resonance method comprising:
loading a subject into a magnetic resonance scanner;
with the subject loaded into the magnetic resonance scanner, acquiring B₁ maps for a plurality of radio frequency transmit channels of the magnetic resonance scanner;
shimming the plurality of radio frequency transmit channels and setting a radio frequency transmit power for the shimmed plurality of radio frequency transmit channels using the acquired B₁ maps to generate optimized amplitude and phase parameters for the plurality of radio frequency transmit channels;
acquiring magnetic resonance imaging data of the subject loaded into the magnetic resonance scanner including exciting magnetic resonance by operating the plurality of radio frequency transmit channels using the optimized amplitude and phase parameters;
generating a reconstructed image from the acquired magnetic resonance imaging data; and
displaying the reconstructed image.

17. The magnetic resonance method as set forth in claim 16, wherein the plurality of radio frequency transmit channels consists of N radio frequency transmit channels and the acquiring B₁ maps for a plurality of radio frequency transmit channels of the magnetic resonance scanner comprises:
acquiring N B₁ maps corresponding to the N radio frequency transmit channels.

18. The magnetic resonance method as set forth in claim 16, wherein the shimming and setting to generate optimized amplitude and phase parameters for the plurality of radio frequency transmit channels comprises:
shimming the plurality of radio frequency transmit channels using the acquired B₁ maps; and
after the shimming, setting the radio frequency transmit power for the shimmed plurality of radio frequency transmit channels using the acquired B₁ maps to generate the optimized amplitude and phase parameters.

19. The magnetic resonance method as set forth in claim 16, wherein the shimming and setting to generate optimized amplitude and phase parameters for the plurality of radio frequency transmit channels comprises:
optimizing the amplitude and phase parameters respective to a figure of merit that combines (i) a measure of radio frequency transmit field uniformity and (ii) a measure of radio frequency transmit field power.

20. The magnetic resonance method as set forth in claim 16, wherein the shimming and setting to generate optimized amplitude and phase parameters for the plurality of radio frequency transmit channels comprises:
setting the radio frequency transmit power for the shimmed plurality of radio frequency transmit channels using the acquired B₁ maps based on a radio frequency transmit power metric selected from a group consisting of (i) average radio frequency transmit power in a region of interest, (ii) average radio frequency transmit power in a slice of interest, and (iii) radio frequency transmit power at a point in space of interest.
